(19) United States
(12) Patent Application Publication
(10) Pub. No.: US 2003/0073311 A1
(43) Pub. Date: Apr. 17, 2003

(54) Compositions and processes for spin etch planarization

(76) Inventors: Joseph Levert, Vista, CA (US); Daniel Towery, Santa Clara, CA (US)

Correspondence Address: Rutan & Tucker, LLP, 14th Floor, 611 Anton Blvd., Costa Mesa, CA, 92626, US

(21) Appl. No.: 10/222,230

(22) Filed: Aug. 15, 2002

Related U.S. Application Data
(62) Division of application No. 09/356,487, filed on Jul. 19, 1999.

(51) Int. Cl. H01L 21/302; H01L 21/461

(52) U.S. Cl. 438/689

(57) ABSTRACT

The present invention describes methods and chemical compositions for the spin etch planarization of surfaces, particularly copper and tantalum. An etching solution is brought into contact with the upper face of a spinning wafer through a nozzle, preferably an oscillating nozzle. The etching solution has a composition that oxidizes the spinning surface, forming a passivation layer thereon. The etching solution further contains reactants for removing the passivation layer exposing the underlying surface to further reaction, leading to the desired etching of the surface. The characteristics of the etching solution are adjusted such that reactant diffusion to lower regions of the surface limits the rate of etching. Faster reaction occurs at higher regions of the surface lying in more rapidly moving etching solution resulting in the desired planarization.

### BACKGROUND OF THE INVENTION

1. Technical Field

This invention relates to chemical etching processes for the planarization of surfaces and chemical compositions especially suited thereto. More particularly, this invention relates to composition and processes for spin etch planarization of surfaces typically encountered in the fabrication of integrated circuits.

2. Description of Related Art

Modern designs for integrated circuits (“ICs”) typically consist of multiple layers of material into which patterns are etched. Commonly, the layers consist of conducting, insulating and semiconductor material etched by means of photolithography (given by way of illustration, not intending to exclude thereby other arrangements of material or other means of patterning or etching). The near-universal trend in the manufacture of integrated circuits is to increase the density of components fabricated onto a given area of wafer, to increase the performance and reliability of the ICs, and to manufacture the ICs at lower cost with less waste and fewer defective products generated by the manufacturing process. These goals lead to more stringent geometric and dimensional requirements in the manufacturing process. In particular, etching precise patterns into a layer is facilitated by the layer having a surface as nearly planar as feasible at the start of the etching process. For the common case of patterning by means of photolithography, a planar surface permits more precise location and dimensioning for focusing the incident radiation onto the surface to be etched than would be possible with a surface having deviations from planarity. Similar conclusions apply for electron beam or other means of etching. That is, deviations from planarity of the surface to be etched reduce the ability of the surface to support precisely positioned and precisely dimensioned patterns. In the following description of the present invention we focus on the typical etching, planarization and patterning processes as practiced in the manufacture of ICs. However, this is by way of illustration and not limitation, as those skilled in the art will appreciate that the techniques of the present invention for producing planar surfaces will have applicability in increasing the precision of etching by means other than photolithography. In addition, the present invention is not limited to the field of IC manufacture and will find applicability in other areas of technology requiring planar surfaces.

One form of chemical etching involves the application of etching reagents to a spinning surface, spin etch planarization (“SEP”). The rotational motion of the substrate undergoing etching causes centrifugal forces on the etching reagent for etchant dispersal and flow over the surface. SEP is a common technique employed for the planarization of semiconductor wafers in the fabrication of IC's and will be the primary focus of our description. However, the present invention is not inherently limited to ICs.

The present invention is described in terms of the common application to performing SEP on films typically arising in the manufacture of IC's, particularly copper. However, the compositions and processes of the present invention are not inherently limited to these particular instances. The techniques and chemical compositions described herein could also find application in the manufacture of devices that make use of manufacturing materials and procedures similar to those used to manufacture ICs. Active matrix displays, microelectromechanical systems (“MEMS”) are but two examples of such similar devices. Others will be apparent to those having ordinary skills in the art.

To be concrete, the description herein is directed chiefly to the planarization of copper films as this specific case is expected to be a prime area of applicability of the present invention. However, the present invention is not inherently so limited. The chemical formulations described herein could be useful for performing SEP on many materials, including but not limited to materials used in the fabrication of multi-layer ICs. Such materials would include aluminum, silicon, tantalum, tungsten, and alloys thereof. Dielectric and refectory materials may also be planarized by SEP according to the chemical formulations and procedures described by the present invention. Specialized materials could also be planarized by the chemical formulations and processes of the present invention including, but not limited to, organic polymers, ceramics, ceramic-organic composites, gallium arsenide, and similar materials apparent to those having ordinary skills in the art.

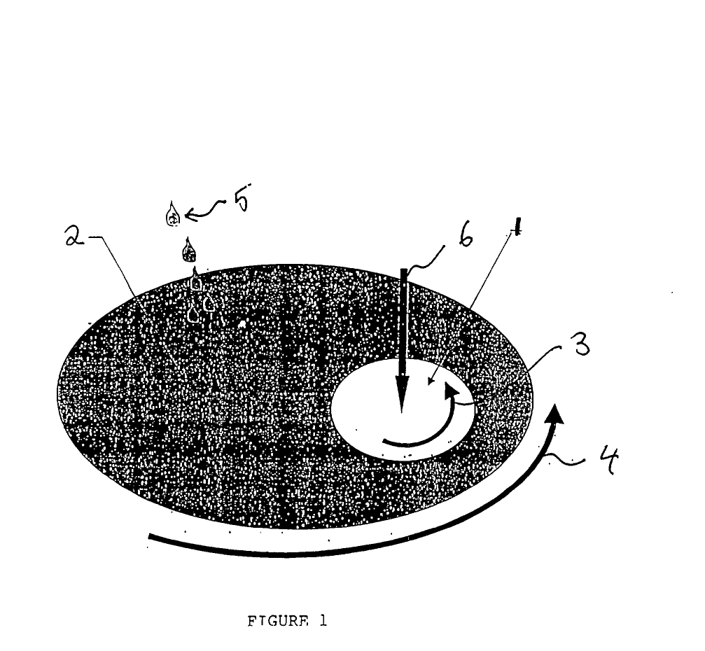

A common method for the planarization (that is, made flat and smooth) of integrated circuit surfaces during the manufacturing process is chemical mechanical polishing (“CMP”) depicted schematically in FIG. 1. CMP typically involves a wafer to be planarized, 1, being pressed firmly against a polishing pad, 2 by means of force, 6, directed substantially perpendicular to the surface of the wafer to be planarized. Typically, the wafer, 1, will be caused to rotate as depicted by 3 in FIG. 1, while the polishing pad will itself rotate (in FIG. 1). FIG. 1 depicts the polishing pad and wafer rotating in the same direction (for example, clockwise when viewed from above as in FIG. 1). However, this is merely for purposes of illustration and counter-rotation of wafer and polishing pad is also practiced.

In addition to the rotation of the wafer depicted by 3 in FIG. 1, the wafer, 1, may be caused to oscillate in the plane of the surface being polished, substantially perpendicular to the plane of the applied force, 6 (This oscillatory motion is not depicted in FIG. 1).

Typically, wafer, 1, is held firmly by a retaining ring fixed to a rotating wafer carrier, commonly gimbaled. The CMP process typically uses an abrasive slurry, 5, continuously introduced (dripped) onto the polishing pad, 2, throughout the planarization process. The abrasive slurry, 6, may also contain chemicals capable of reacting with the material to be removed from the surface of wafer, 1, the reaction products leaving the wafer's surface. Thus, CMP typically employs both mechanical abrasion and chemical reactions to remove material from the surface of wafer 1 to achieve a planar surface.

The polishing pad, 3, is typically made of polyurethane or fibers impregnated with polyurethane, although other materials may also be used. The polishing pad is typically attached to a rigid, temperature controlled platen and rotated as depicted schematically in FIG. 1.

Several significant drawbacks occur in the practice of CMP, many of which relate to the use of polishing pad, 3. The polishing pad accumulates abrasive slurry and excess chemical reactive materials as well as material removed from the wafer both by abrasion and chemical reaction. Thus, the polishing pad requires an additional process commonly referred to as “pad conditioning” typically performed concurrently with the planarization of the wafer depicted in FIG. 1. Pad conditioning relates to the process of removing contaminants from the polishing pad to avoid degradation in performance from one wafer to the next or, in some cases, during the processing of a single wafer. Without pad conditioning, the removal rate, uniformity and planarity of the wafer material is unstable from wafer to wafer making it impossible to use CMP in practical IC production processes.

Pad conditioning is typically performed with diamond-impregnated ring or disk tools pressed against the rotating polishing pad. This process removes from the polishing pad material removed from the wafer surface including CMP reaction products, abraded materials and unconsumed abrasive, reactive slurry, 5. Pad conditioning is thus necessary to prevent material build-up on the pad and the attendant degradation in performance. However, diamonds may occasionally fall from the pad conditioning disk onto polishing pad, 2, resulting in scratches on the surface of wafer, 1.

Following a typical CMP, a cleaning operation is typically required of the polishing pad, 2, to remove as many contaminants resulting from the planarization process as possible. This post-CMP cleaning is typically performed by scrubbing with a mechanical brush with the application of specialized cleaning chemicals. Such post-CMP cleaning of the polishing pad increases the complexity of the overall CMP process requiring additional process tools, processing time and additional consumable items such as the cleaning chemicals. Thus, while CMP has generally been successful in planarizing surfaces, it is a costly and complicated process with numerous processing parameters that have been difficult to control precisely in typical manufacturing environments.

Chemical etching has been used for planarization in the work of Cibulsky et. al. (U.S. Pat. No. 5,759,427) in combination with a mechanical head contacting and rubbing the surface of the substrate during processing. In this work, a chemical etching solution and rotating planarizing head are brought into contact with the surface to be planarized. Abrasive additives are used in one embodiment of the Cibulsky invention, thereby introducing solids into an otherwise all liquid etching solution.

While CMP has been successfully employed in many planarization processes, it has several disadvantages which the present invention intends to reduce or eliminate. As noted above, CMP is a rather complex and costly multi-step process having many processing parameters that are generally difficult to control in a practical manufacturing environment. In addition, CMP is a mechanical process subjecting the wafer (typically a multi-layer IC) to shear stresses. Some of the IC layers may consist of films having low dielectric constant, that are often mechanically weak relative to conventional dielectrics, tending to delaminate under the shear stress of CMP. Application of shear stress is contraindicated for such layers and may result in damage.

The downward force, 6, causing contact between the wafer, 1, and polishing pad, 2, typically will be sufficient to cause a small amount of deflection in the surface of polishing pad, 2. Polishing by means of a deflected pad will typically result in removal of material from the surface being polished partially from lower regions of the surface which are not readily accessible to a flat polishing pad. Thus, polishing with a deflected pad will require a longer time and the removal of more material to achieve planarity than would use of a nondeflected, flat polishing pad.

Abrasive or other particles from slurry, 5, may contaminate the surface of wafer, 1 or result in scratches therein. Both are undesirable. The presence of solid material in slurry, 5, makes reclaiming or recycling the slurry impractical and complicates the processing of the waste from CMP planarization. The present invention intends to reduce or eliminate some or all of these disadvantages in conventional CMP planarization, resulting thereby in improved planarization.

The present invention relates to spin etch planarization (“SEP”) as a method for removing material and forming a highly planar surface. SEP offers several potential advantages over CMP. Among these are the possibility of reclaiming for reuse chemical reagents not consumed by SEP processing, thereby reducing waste of reagents and lowering processing costs. Contaminated, reacted or otherwise non-reusable reagents are typically liquids in SEP, lacking the significant amount of dissolved solids generally found in CMP. Therefore such SEP by-products are generally more easily treated. Further lowering the cost of SEP over CMP is the relatively less complex machinery and associated equipment required by SEP.

All-liquid chemical etching (or polishing) of copper is typified by the work of Tytgat and Magnus (U.S. Pat. Nos. 4,981,553 and 5,098,517). In this work, a solution of chemicals capable of etching the substrate (typically copper) at the required rate and uniformity is described along with typical conditions of use. Typically, the surface to be etched is dipped, immersed or otherwise bathed in the etching solution for the appropriate amount of time.

The present invention uses chemical etching to planarize a surface, typically copper, by spin etching without the need for bringing the surface into contact with a rotating polishing pad or similar device. The present invention has only chemical etchants in a liquid form contacting the spinning surface undergoing planarization. The etching chemicals and conditions for use described in the present invention provide adequate control of the etching process to achieve adequate planarization in reasonable amounts of time while reducing or eliminating many of the drawbacks associated with CMP as described above.

### BRIEF SUMMARY OF THE INVENTION

The present invention describes methods and chemical compositions for the spin etch planarization of surfaces, particularly copper and tantalum as would be applicable in the fabrication of integrated circuits. A wafer is spun with the face to be planarized facing upward. An etching solution is brought into contact with the spinning face through a nozzle. The introduction of etching solution through an oscillating nozzle is preferred. The etching solution has a composition that oxidizes or otherwise reacts with the surface to be etched forming a passivation layer thereon. The etching solution further contains reactants for removing the passivation layer exposing the underlying surface to further reaction, leading to the desired etching of the surface. The characteristics of the etching solution are adjusted such that relatively slow rates of diffusion deliver reactants to lower regions of the surface. Higher regions of the suffice lie further from the boundary layer in faster-moving etching solution, less susceptible to diffusion limitations on reaction rates. Thus, faster reaction occurs at higher regions of the surface than at lower, resulting in the desired planarization. A primary advantage of the present invention is to provide planarization of a surface without mechanical contact or mechanical abrasion.

### BRIEF DESCRIPTION OF THE SEVERAL VIEWS OF THE INVENTION

The drawings are schematic only and not to scale.

FIG. 1: Schematic depiction of Chemical Mechanical Polishing (“CMP”).

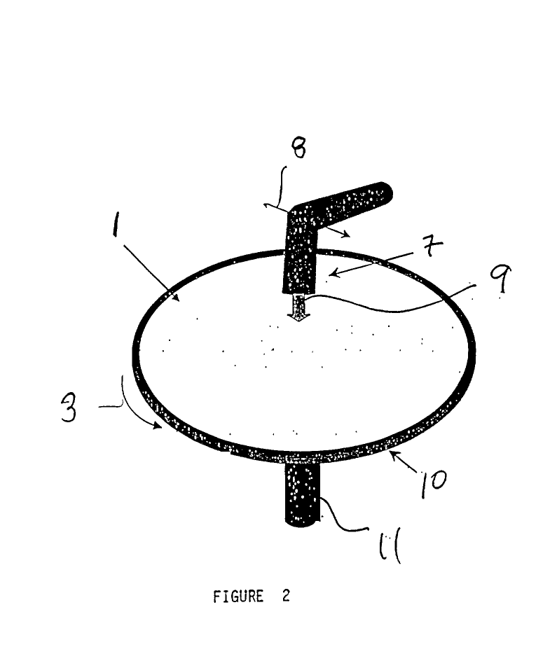

FIG. 2: Schematic depiction of Spin Etch Planarization (“SEP”) of the present invention.

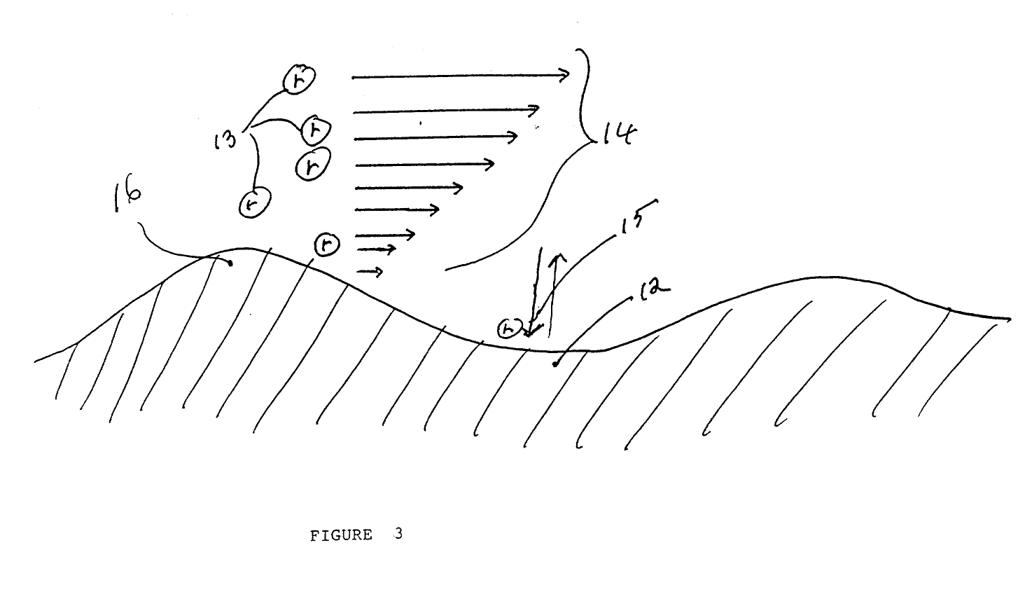

FIG. 3: Cross-sectional, magnified schematic depiction of liquid-solid interface, boundary layer, flow and diffusion of reagents.

### DETAILED DESCRIPTION OF THE INVENTION

In the following description and figures, similar reference numbers are used to identify similar elements.

A schematic depiction of one embodiment of the present invention is given in FIG. 2. Wafer, 1, is typically held in wafer chuck, 10, while rotated about axis, 11, in direction 3. The precise speed of rotation of the wafer has not proven to be highly sensitive in the practice of the present invention. Rotation speeds from almost zero up to about 5000 rpm give adequate results in the practice of the present invention.

The etching solution or reagent, 9, is typically directed onto the wafer, 1, through a reagent inlet nozzle, 7. In this embodiment of the present invention, reagent nozzle, 7, is traversed or oscillated above the surface to be etched as denoted by 8 in FIG. 2. It is found in the practice of the present invention that rotation of the wafer under a fixed reagent inlet nozzle is acceptable but not optimal for achieving uniform planarization. Therefore, reagent inlet nozzle, 9, is moved above the surface to be planarized, 1. Oscillatory motion of 7 as denoted by 8 in FIG. 2 is found to be one technique to achieve efficient planarization in the practice of the present invention. Rates of oscillation from zero to several hundred cycles per second are adequate in the practice of the present invention.

The amplitude of nozzle oscillation depicted in FIG. 2 is not critical to the practice of the present invention. Adequate results are obtained with oscillations as large as the full diameter of the wafer while no oscillation at all gives acceptable results.

FIG. 2 depicts etching reagent, 9, directed onto the surface of the wafer through a nozzle, 7, having a diameter about 10% of the diameter of the wafer. This is by way of illustration and not a limitation on the practice of the present invention. Nozzle diameters as large as the wafer itself and as small as about a few percent of the wafer diameter, and having intermediate dimensions, are acceptable in the practice of the present invention. The size of the nozzles is not a highly critical parameter in the practice of the present invention, related to the fact that the flow rate of reagent onto the wafer is likewise not a highly critical parameter. Flow rates of reagent from almost zero to several liters per second are found to be adequate in the practice of the present invention.

Some embodiments of the present invention may make use of external heating applied to the surface of the wafer, 1, to activate or increase the rate of the etching reaction(s). Such sources of heat are not depicted in FIG. 2 but would consist of conventional sonic, infrared, microwave or other means for heating known in the art, directing heat onto wafer, 1. similarly, the temperature of the etching reagent, 9, may be controlled to facilitate SEP in accordance with the present invention.

Other embodiments of the present invention consist of directing a plurality of reagents onto wafer 1 through a plurality of nozzles 7 (not depicted in FIG. 2) or, alternatively, through different segments of a single multichannel nozzle. Mixing of such reagents on, or just prior to, contacting the surface to be planarized in certain cases would generate heat of mixing, chemical reactions, or other chemical or physical effects assisting the SEP processing of the present invention.

Physical mixing of multicomponent reagents at, or just prior to, contacting the surface to be etched are examples of embodiments of the present invention in which physical or chemical effects helpful for SEP are induced at or near the time of etching. However, the physical mixing of multicomponent reagents is just one of the possible ways to achieve these useful effects. Other methods include heating the reagent(s) at, or just prior to, contacting the surface. Reagents can be heated before delivery to the surface by means of passage through a heat exchanger, typically a tubular heat exchanger immersed in a constant temperature bath. Heating at the surface (or in close proximity) may be accomplished by heating the reagents with directed sonic energy, electromagnetic heating via microwave, infrared or the like. In addition to heating reagents, specific chemical effects may be introduced into the reagent(s) at, or just prior to, contacting the surface to be etched. Specific chemical effects may be achieved by photochemical excitation or one or more species within the reagent mixture, sonic excitation of specific reaction(s) or other catalytic means employed at, or near, the surface to be etched. Combinations of some or all of the above processes may be employed in the practice of the present invention.

The SEP process according to the present invention makes use of several general classifications of chemical mechanisms, singly or in combination. These are:

a) Diffusion controlled reactions to etch preferentially protruding regions of the surface, thereby facilitating planarization.

b) Balanced oxidation and reduction of oxide to facilitate uniform removal of material from successive surface layers.

c) Self-galvanic microcouples on the surface being etched, facilitating uniform galvanic action on a very fine dimensional scale for uniform removal of material and avoidance of pitting.

d) Additive chemicals to assist in achieving selective removal of multiple layers of different materials without losing planarization.

a) Diffusion Controlled Reactions

Important controls in the present SEP processes are achieved by making use of diffusion-limited reactions. That is, the physical contact of the reagent(s) used in the practice of the present invention affect the chemical etch processes occurring on the surface to be planarized. A combination of reagents, diluents (inert solvents carrying the reactive etching species), temperatures and other conditions, are selected such that diffusion of the reagents through solution and to the reaction sites on the surface determine the rate of SEP. Thus, diffusion in the direction normal to the surface is an important reaction-controlling mechanism in the present invention. Were this not the case, mechanical control of SEP by wafer rotation, nozzle oscillation, and other factors described above, would be largely ineffective in controlling the SEP process. Thus, SEP conditions are employed in the practice of the present invention in which SEP is affected by the diffusion of reagents to the surface (and/or diffusion of reaction products away from the surface).

It is generally understood in the flow of liquids over surfaces that a substantially stationary boundary layer occurs at the liquid-solid interface, and liquid flow increases in velocity (in a direction parallel to the surface) with increasing distance away from the surface until achieving the flow rate of the bulk liquid in the absence of a surface. This is generally true for smooth as well as rough surfaces as depicted in FIG. 3. The relatively higher regions of the surface to be etched tend to encounter more rapidly moving fluids. In the practice of the present invention, the moving fluid is the etching reagent(s). Thus, under diffusion-limited reaction conditions, the higher regions of the surface to be etched encounter more etching reagent(s). This etches the higher regions more rapidly than the recessed regions, the products of which can diffuse downward to the surface to be etched, leading to the desired planarization effects of the present invention.

Specifically, 14 in FIG. 3 depicts the gradient of fluid velocities increasing with distance from the surface of the solid, 12. Thus reagent species, 13, more readily flow past the upward-projecting portions of the surface (schematically 16 in FIG. 3) continually replenishing the fluid in contact with such elevations with etching reagent. Lower region, 12 in FIG. 3, do not typically contact faster flowing portions of the reagent stream, 14, as it moves across the surface, 12, of the wafer to be planarized. Under the reaction conditions of the present invention, reaction rates leading to planarization are typically diffusion-limited. Thus, the relatively higher fluid flow in the vicinity of region 16 in comparison with region 12 tends to more rapidly etch region 16, facilitating planarization.

The near-stagnant fluid in the lower regions (adjacent the surface) requires that the active chemical etching species diffuse vertically downward for a substantial distance, which occurs rather slowly under typical reaction conditions obtaining during SEP. This slow diffusion process typically limits the total supply of etchant at the reaction sites thereby limiting the etch rate. Therefore, SEP as practiced pursuant to the present invention involves diffusion-limited reactions steps.

In contrast to the near-stagnation of reagent in the regions near the surface, rapid flow of reagents just above the protruding regions continually replenishes the etchant species in these local regions. The relatively small vertical distance from the flowing etchant to the protruding portions of the surface allows a greater cumulative supply of etchant species to reach these regions by diffusion. Thus, greater reaction rates at protruding regions of surface are expected, resulting in greater etch rates for protruding regions than for lower surface regions. Surface planarization follows as the protruding regions are etched more rapidly.

When operating under diffusion-limited conditions, the physical properties of the reagent solution affecting diffusion become important as well as the chemical properties. Thus additives controlling viscosity, surfactants, wetting agents, and other diffusion-altering additives, all have a role in affecting the diffusion properties of the reagent solution. Temperature also affects diffusion as well as some chemical reactions and is, therefore, also a useful parameter to control in some embodiments of the present invention.

b) Balanced Oxidation and Reduction

Effective planarization making use of the SEP of the present invention involves a combination of chemical species and chemical reactions. One such reaction is the oxidation of the surface to form an oxide in combination with reaction with a co-reactant selected so as to reduce or otherwise remove the oxide thus formed.

Oxidation by a suitable oxidizing species uniformly oxidizes the copper surface thereby “passivating” the metal. The oxide or similar passivation film partially protects the underlying metal layer (typically copper in the present example) which thereby limits further oxidation of the metal. Accelerated local oxidation of the metal frequently results in pitting and/or loss of surface planarity.

As the passivation firm is formed, reaction with a co-reactant occurs. The co-reactant is chosen so as to remove the passivation film by reduction or some other chemical mechanism. The co-reaction to remove the passivation film needs merely to produce a reaction product that dissolves and is removed by the chemical solution in the vicinity of the surface. The newly exposed metal surface is again exposed to oxidation, formation of a passivation layer and removal by co-reactant. This cycle recurs many times during SEP and is helpful in maintaining planarity in the practice of the present invention.

c) Self-Galvanic Microcouple

Microscopic differences in the surface structure and chemical environment of materials lead to different regions of the same surface having different electrochemical properties. Regions of pure metal, grain boundaries, other defects or dislocations are sufficient to provide regions having different electrochemical potentials. Thus, self-galvanic microcouples arise connecting such regions as anode and cathode, leading to electrochemical removal of material, typically by means of an oxidation/reduction reaction set. These surface non-uniform regions leading to self-galvanic couples occur uniformly over the surface and have microscopic dimension (“microcouples”). Thus, such galvanic couples lead to material removal on a very fine scale, avoiding removal of large amounts of material from any localized area (commonly resulting in pitting).

d) Additive Chemicals

In combination with any other embodiment of the present invention, additive chemicals may be introduced into the reagent mixture for the purpose of modifying (typically slowing) reaction rates. Other uses for chemical additives include enforcing a more uniform chemical reactivity over a wider surface area and assisting in allowing preferential removal of one type of metal in preference to another when processing bimetallic or multimetallic layers. Such chemical inhibitors are chosen to ensure that the material removal is done without loss of planarization.

The present invention is not limited to a single SEP step. Multiple steps are included within the scope of the present invention. Examples include application of multiple chemical reactive solutions, possibly including an initial passivation step followed by application of a reagent mixture which equally passivates and dissolves the surface yielding thereby a controlled, smooth planar surface. This procedure could typically be followed by a final etching step to remove and passivate material, followed by a final rinse (typically with de-ionized water) for cleaning.

Other embodiments of the present invention relate to the chemical etch planarization of surfaces in which more than one substance is exposed to the etching reagent(s). In this embodiment, the reagent mixture may contain surfactant chemicals that preferentially bind to one (or some) of the exposed substances or selectively alter the chemical properties of one (or some) of the surface constituent materials. Preferential etching follows, typically resulting in selective planarization of the surface in this embodiment of the present invention.

We note elsewhere herein typical components of the etching reagents useful in the practice of the present invention. Practical industrial applications may also require the reagent mixture to contain other additives to inhibit premature reaction, stabilize the mixture, increase shelf life of the reagent mixture, reduce volatility, inhibit toxicity, inhibit photodegredation, and the like. Such additives are known to those skilled in the art and are not otherwise specified in detail herein.

Another class of additives are those that affect the viscosity of the etchant with minimal effects on the etchant's chemical etching capability. These viscosity modifiers (such as glycols) affect the thickness and velocity distribution of the boundary layer. Modifying the boundary layer assists in modifying the diffusion-controlled reaction mechanism to achieve planarization of non-planar surfaces.

Tables 1-10 following are examples of reagent mixtures usefully employed in the practice of the present invention for planarizing copper surfaces or other surfaces as indicated on the Tables. Other combinations of reagents applicable to other surfaces are known to those having ordinary skills in the art.

TABLE 1
AQUEOUS PEROXIDE—PHOSPHORIC ACID REAGENT
SOLUTIONS FOR PLANARIZATION OF COPPER

| Oxidizer | Co-Reactant | Other Additives |
|---|---|---|
| a) H₂O₂ | H₃PO₄ | HCl, aliphatic alcohols |
| b) H₂O₂ | H₃PO₄ | HCl, |
| | | Agidol (butylated |
| | | hydroxytoluene) |
| c) H₂O₂ | H₃PO₄ | HCl, 2,6-di-tert-butyl- |
| | | 4[(dimethylamino) |
| | | methyl]phenol |
| d) H₂O₂ | H₃PO₄ | HCl; H₃PO₄, |
| | | (HPO₄)²⁻, PO₄³⁻ |
| e) H₂O₂ | H₃PO₄ | HCl, 2,6-di-tert- |
| | | -4N,N-dimethyl |
| | | aminomethylphenol |
| g) H₂O₂ | H₃PO₄ | borax |
| h) H₂O₂ | H₃PO₄ | various additives |

TABLE 2
AQUEOUS PEROXIDE—SULFURIC ACID REAGENT
SOLUTIONS FOR PLANARIZATION OF COPPER

| Oxidizer | Co-Reactant | Other Additives |
|---|---|---|
| a) H₂O₂ | H₂SO₄ | Ethylene glycol, |
| | | ZnSO₄ |
| b) H₂O₂ | H₂SO₄ | MeOH, Poly(oxy |
| | | ethylene)lauryl ether, |
| | | Malic acid |
| c) H₂O₂ | H₂SO₄ | HOOC(CX₂)ₙCOOH |
| | | with X = OH, amine, H |
| | | n = 1 − 4 |
| d) H₂O₂ | H₂SO₄ | 3% tartaric acid |
| | | 1% ethylene glycol |
| e) H₂O₂ | H₂SO₄ | 1,2,4-triazole, |
| | | 1,2,3-triazole, |
| | | tetrazole, |
| | | nonionic surfactant |
| f) H₂O₂ | H₂SO₄ | C₂H₅OH, aliphatic |
| | | alcohols, |
| | | nonionic surfactant |
| g) H₂O₂ | H₂SO₄ | Triflouroethanol, |
| | | Laprol 602 ® surfactant, |
| | | aliphatic alcohols |
| h) H₂O₂ | H₂SO₄ | aliphatic alcohols |
| i) H₂O₂ | H₂SO₄ | SiF₆, Organic salt |
| | | surfactant |
| j) H₂O₂ | H₂SO₄ | various additives |

TABLE 3
AQUEOUS PEROXIDE MINERAL ACID REAGENT SOLUTIONS
FOR PLANARIZATION OF COPPER

| Oxidizer | Co-Reactant | Other Additives |
|---|---|---|
| a) H₂O₂ | HNO₃ | alcohols, |
| | | HOOC(CX₂)ₙCOOH |
| | | X = OH, amines, H |
| | | n = 1 − 4 |
| b) H₂O₂ | HNO₃ | various additives |

TABLE 4
AQUEOUS NITRIC ACID REAGENT SOLUTIONS FOR
PLANARIZATION OF COPPER

| Oxidizer | Co-Reactant | Other Additives |
|---|---|---|
| a) H₂O₂/HNO₃ | H₃PO₄ | Methanol |
| b) H₂O₂/HNO₃ | | Triflouroethanol, |
| | | Laprol 602 ® |
| | | Surfactant, aliphatic |
| | | alcohols |
| c) HNO₃ | H₃PO₄ | Polyvinyl alcohol |
| d) HNO₃ | H₂SO₄ | diphenylsulfamic acid, |
| | | aliphatic alcohols |
| e) HNO₃ | H₂SO₄ | HCl |
| f) HNO₃ | H₂SO₄ | various additives |

TABLE 5
AQUEOUS PEROXIDE ORGANIC ACID REAGENT SOLUTIONS
FOR PLANARIZATION OF COPPER

| Oxidizer | Co-Reactant | Other Additives |
|---|---|---|
| a) H₂O₂ | Oxalic acid | Sodium oxalate, |
| | | Benzotriazole, |
| | | Sodium Lignosulfonate |
| b) H₂O₂ | other organic | various additives |
| | acids | |

TABLE 6
AQUEOUS CONCENTRATED ACID REAGENT SOLUTIONS FOR
PLANARIZATION OF COPPER

| Oxidizer | Acids | Other Additives |
|---|---|---|
| a) | H₃PO₄/Acetic/H₂SO₄ | |
| b) | H₃PO₄/Acetic/HNO₃ | |
| c) | H₃PO₄/Acetic/HNO₃/H₂SO₄ | Glycol, Gelatin |
| | | Carboxymethyl- |
| | | cellulose, amines, |
| | | surfactants, heavy |
| | | metal salts including |
| | | Cu and Ta. |
| d) H₂O₂ | H₃PO₄/Acetic/H₂SO₄ | Glycol, Gelatin |
| | | Carboxymethyl- |
| | | cellulose, amines, |
| | | surfactants, heavy |
| | | metal salts including |
| | | Cu and Ta. |
| e) H₂O₂ | H₃PO₄/H₂SO₄ | 100 ml propylene |
| | | glycol, 100 ml 2-ethyl- |
| | | hexylamine, 25 ppm |
| | | Cl⁻. |
| f) | H₃PO₄/Acetic/HNO₃ | nonionic surfactant |
| g) H₂O₂ | H₃PO₄/Acetic/HNO₃/H₂SO₄ | various additives |

TABLE 7
AQUEOUS DILUTE ACID—METAL SALT REAGENT SOLUTIONS
FOR PLANARIZATION OF COPPER

| Oxidizer | Acid | Metal Salt | Other Additives |
|---|---|---|---|
| a) | HCl | CuCl | |
| b) | HCl | CuCl | KCl |
| c) | HCl | FeCl | various additives |
| d) H₂O₂ | H₂SO₄ | CuCl | n-propanol |
| e) | HCl | CuCl | various additives |
| f) H₂O₂ | H₂SO₄ | CuCl | n-propanol |

TABLE 8
AQUEOUS DILUTE BASE—METAL SALT REAGENT
SOLUTIONS FOR PLANARIZATION OF COPPER

| Oxidizer | Base | Metal Salt | Other Additives |
|---|---|---|---|
| a) NaClO₃ | NH₄F | CuSO₄ | Na EDTA salt of |
| | | | wetting agent |

TABLE 9
AQUEOUS ACID/BASE REAGENT SOLUTIONS FOR
PLANARIZATION OF TANTALUM

| Oxidizer | Acid | Base | Other Additives |
|---|---|---|---|
| a) HNO₃ | HF | | various additives |
| b) H₂O₂ | HF | | various additives |
| c) H₂O₂ | | NaOH | various additives |
| d) H₂O₂ | | KOH | various additives |

TABLE 10
MISCELLANEOUS REAGENTS FOR PLANARIZATIONS
OF COPPER

| | |
|---|---|
| a) | EDTA, NH₄OH, H₂O₂, in aqueous solution |
| b) | Citric acid, Erythorbic acid, Triethanolamine, in aqueous solution |
| c) | Trisodium citrate, Triethanolamine, Sodium nitrate, in |
| | aqueous solution |
| d) | H₂SO₄, H₂O₂, Sodium molybdate, Phenolsulfonic acid, in aqueous |
| | solution |
| e) | Mineral acid (sulfuric, HCl or the like), molybdenum salt |

In addition to the additives shown in Tables 1-10 above, other additives include but are not limited to the following:

borax, zinc sulfate, copper carbonate, alcohol (including low molecular weight alcohols, glycols, phenols, aliphatic alcohols, polyvinylalcohols and the like), surfactants (including anionic, cationic, fluorocarbon-based surfactants, nonionic surfactants and other surfactants preferentially adhering to certain materials, modifying thereby the chemical reactivity of certain sites), solution stabilizers (including polyvinyl alcohols and other agents inhibiting spontaneous decomposition of oxidizing agents), wetting agents.

Having described the invention in detail, those skilled in the art will appreciate that, given the present disclosure, modifications may be made to the invention without departing from the spirit of the inventive concept described herein. Therefore, it is not intended that the scope of the invention be limited to the specific and preferred embodiments illustrated and described. Rather, it is intended that the scope of the invention be determined by the appended claims.

We claim:

1) An etching solution for use in planarization of a surface comprising:
a) an oxidizing reactant having the property of oxidizing said surface and forming a passivation layer thereon; and,
b) a depassivating co-reactant having the property of reacting with said passivation layer and terminating the passivation property of said passivation layer; and,
c) a means for adjusting the diffusion of said oxidizing reactant and said depassivating co-reactant such that rates of reactions occurring in depressed regions of said surface are diffusion-limited and have slower rates than reactions occurring at elevated regions of said surface.

2) An etching solution as in claim 1 wherein said surface is copper; and,
said oxidizing reactant is selected from the group consisting of, H₂O₂, HNO₃ and mixtures thereof; and,
said depassivating co-reactant is selected from the group consisting of: H₃PO₄, H₂SO₄, HNO₃, oxalic acid, acetic acid, organic acids and mixtures thereof; and,
said means for adjusting diffusion comprises an additive selected from the group consisting of HCl, aliphatic alcohols, butylated hydroxytoluene, 2,6-di-tert-butyl-4[(dimethylamino)methyl]phenol, 2,6-di-tert-4N,N-dimethylaminomethylphenol, borax, ethylene glycol, ZnSO₄, methanol, propanol, poly(oxyethylene)lauryl ether, malic acid, HOOC(CX₂)ₙCOOH wherein X═OH, amine, H and n=1-4), 3% tartaric acid, 1% ethylene glycol, 1,2,4-triazole, 1,2,3-triazole, tetrazole, nonionic surfactant, ethanol, triflouroethanol, SiF₆, organic salt surfactant, polyvinyl alcohol, diphenylsulfamic acid, sodium oxalate, benzotriazole, sodium lignosulfonate, glycol, gelatin carboxymethylcellulose, amines, heavy metal salts, salts of Cu and Ta, propylene glycol, 2-ethyl-hexylamine, copper carbonate, low molecular weight alcohols, glycols, phenols, aliphatic alcohols, polyvinylalcohols, anionic surfactants, cationic surfactants, fluorocarbon-based surfactants, nonionic surfactants having the properties of preferentially adhering to certain materials, modifying thereby the chemical reactivity where so adhered, polyvinyl alcohol solution stabalizers and species inhibiting spontaneous decomposition of oxidizing agents, wetting agents and mixtures thereof.

3) An etching solution as in claim 2 further comprising a species selected from the group consisting of: CuCl, FeCl, KCl and mixtures thereof.

4) An etching solution as in claim 2 wherein said oxidizing reactant is NaClO₃, said depassivating co-reactant is a mixture of NH₄F and CuSO₄ and said additives are sodium EDTA salt of a wetting agent.

5) An etching solution as in claim 1 wherein said surface is tantalum; and,
said oxidizing reactant is selected from the group consisting of, H₂O₂, HNO₃ and mixtures thereof; and,
said depassivating co-reactant is selected from the group consisting of HF, H₂O₂, NaOH and KOH.

6) An etching solution as in claim 1 wherein said surface is copper and said etching solution comprises: EDTA, NH₄OH, and H₂O₂, in aqueous solution.

7) An etching solution as in claim 1 wherein said surface is copper and said etching solution comprises: citric acid, erythorbic acid, triethanolamine, in aqueous solution.

8) An etching solution as in claim 1 wherein said surface is copper and said etching solution comprises: trisodium citrate, triethanolamine, sodium nitrate, in aqueous solution.

9) An etching solution as in claim 1 wherein said surface is copper and said etching solution comprises: H₂SO₄, H₂O₂, sodium molybdate, phenolsulfonic acid, in aqueous solution.

10) An etching solution as in claim 1 wherein said surface is copper and said etching solution comprises: mineral acid, molybdenum salt.

11) A method of planarization of a substrate comprising the steps of:
a) spinning said substrate in an orientation having the face to be planarized upward; and,
b) directing an etching solution onto the face of said substrate wherein said etching solution comprises:
i) an oxidizing reactant having the property of oxidizing said surface and forming a passivation layer thereon; and,
ii) a depassivating co-reactant having the property of reacting with said passivation layer and terminating the passivation property of said passivation layer; and,
c) adjusting the diffusion of said oxidizing reactant and said depassivating co-reactant such that rates of reactions occurring in depressed regions of said surface are diffusion-limited and have slower rates than reactions occurring at elevated regions of said surface.

12) A method of planarization as in claim 11 wherein said etching solution is directed onto said face of said substrate through an oscillating nozzle.

13) A method of planarization as in claim 11 wherein said etching solution is directed onto said face of said substrate through an nozzle traversing said face.

14) A method of planarization as in claim 11 wherein constituents of said etching solution are directed onto said face of said substrate separately through multiple nozzles.

15) A method of planarization as in claim 11 wherein the temperature of said etching solution is adjusted prior to directing said etching solution onto said face.

16) A method of planarization as in claim 11 wherein the temperature of said face is controlled.

17) A method of planarization as in claim 11 wherein the said etching solution is photochemically activated prior to directing said etching solution onto said face.
